(19) United States
(12) Patent Application Publication
(10) Pub. No.: US 2009/0032813 A1
(43) Pub. Date: Feb. 5, 2009

(54) Test Wafer, Manufacturing Method Thereof and Method for Measuring Plasma Damage

(76) Inventors: Sung Kun Park, Cheongju-si (KR); Kun Hyuk Lee, Dobong-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/178,091

(22) Filed: Jul. 23, 2008

(30) Foreign Application Priority Data
Aug. 3, 2007 (KR) 10-2007-0077995

(51) Int. Cl. H01L 23/58; H01L 21/00; G01R 31/26

(52) U.S. Cl. 257/48; 438/11; 324/765; 257/E23.179

(57) ABSTRACT

Embodiments of the present invention provide a test wafer capable of analyzing plasma damage, a manufacturing method thereof, and a method for measuring plasma damage using the same. A test wafer according to an embodiment includes a transistor device having at least one probe contact and a gate insulating film comprising a charging trap layer. The plasma process in the process for manufacturing the semiconductor device can be optimized by using the test wafer to determine plasma damage, making it possible to inhibit defect occurrence and malfunction of the semiconductor device and extend the life of the gate insulating layer.

### CROSS-REFERENCE TO RELATED APPLICATION

The present application claims the benefit under 35 U.S.C. 119(e) of Korean Patent Application No. 10-2007-0077995, filed Aug. 3, 2007, which is hereby incorporated by reference in its entirety.

### BACKGROUND

Currently, the high integration of a semiconductor device has been enhanced with the development and advancement of photo-lithography technology.

Also, the high integration has been enhanced with the development and advancement of etching processes, such as, for example, a plasma process, a reactive ion etching (RIE) process, etc.

In order to manufacture a highly integrated high speed semiconductor device, a process for forming a multi-metal layer is needed. Currently, the process for forming the multi-metal layer is a process for forming the metal layers of five or six layers. In this case, a plasma process may be applied as an etching process. Therefore, the use of the plasma process has gradually been increased.

As such, with the increase of the integration degree of the semiconductor device, a line width of a device circuit is narrow so that a high-density plasma (HDP) etching is used to etch the narrow line width.

However, when HDP etching is used to etch gate electrodes/lines of a semiconductor device, the high density plasma forms a strong electric field between a substrate and a gate of the semiconductor device, which can cause severe charging damage to a gate insulating layer.

The damage to the gate insulating layer in a circuit within the device caused by the high density plasma process can affect characteristics of the device, including causing a shift of threshold voltage, sub threshold slope, metal conductance Gₘ, degradation of drain current I_{dsat}, and life shortening of gate insulating layer conductance Gₒₓ. These effects may result in the malfunction of the semiconductor device.

### BRIEF SUMMARY

Embodiments of the present invention provide a test wafer capable of analyzing plasma damage, a manufacturing method thereof, and a method for measuring plasma damage using the same.

A test wafer according to an embodiment includes a plurality of transistor devices arranged on a semiconductor substrate separated from each other in a predetermined interval, each transistor device including a charging trap layer and at least device layer probe contact.

In a test wafer according to an embodiment including monitoring devices each having at least one probe contact and being arranged on a semiconductor device separated from each other in a predetermined interval, the monitoring device can include a gate pattern formed on the semiconductor substrate, a charging trap layer formed between the semiconductor substrate and the gate pattern for trapping plasma ions around the wafer, and a source region and a drain region formed on the semiconductor substrate at sides of the gate pattern.

A method for manufacturing a test wafer according to an embodiment can include forming an insulating film formed of a lower oxide film, a nitride film, and an upper oxide on a semiconductor substrate; forming a gate layer on the insulating film; forming a gate pattern and an insulating pattern by patterning the gate layer and the insulating film; and forming a source region and a drain region by implanting impurities into the semiconductor substrate at sides of the gate pattern.

A method for measuring plasma damage using a test wafer according to an embodiment includes preparing a test wafer comprising transistor devices having at least one probe contact arranged on a semiconductor device separated from each other in a predetermined interval, each transistor device including a charging trap layer within a gate insulating layer pattern; providing the test wafer to a plasma chamber; performing a plasma processing on the test wafer; and measuring an amount of charge trapped in the charging trap layer by probing the probe contact of one of the transistor devices of the test wafer.

The plasma processes in the process for manufacturing the semiconductor device can be optimized by using the measurements taken from the test wafer, making it possible to inhibit defect occurrence and malfunction of the semiconductor device. In addition, the life of a gate insulating layer can be extended.

### BRIEF DESCRIPTION OF THE DRAWINGS

FIG. 1 is a plan view showing a test wafer according to an embodiment of the present invention.

FIG. 2 is a plan view showing a device for monitoring a test wafer formed on the test wafer according to an embodiment of the present invention.

FIG. 3 is a cross-sectional view showing a device for monitoring a test wafer according to an embodiment of the present invention.

FIG. 4 is a flow chart showing a manufacturing process of a test wafer according to an embodiment of the present invention.

FIG. 5 is a flow chart showing a method for evaluating plasma damage using a test wafer according to an embodiment of the present invention.

FIG. 6 is a cross-sectional view showing an operation of a device for monitoring a test wafer according to an embodiment of the present invention.

FIG. 7 is a view showing an energy barrier of each layer of a device for monitoring a test wafer according to an embodiment of the present invention.

FIG. 8 is a graph illustrating threshold voltage provided by probing a device for monitoring a test wafer formed on the test wafer according to an embodiment of the present invention.

### DETAILED DESCRIPTION

Hereinafter, a test wafer, a manufacturing method thereof, and a method for measuring plasma damage using the same will be described with reference to the accompanying drawings. It should be understood that the examples and embodiments described herein are for illustrative purposes only and that various modifications or changes in light thereof will be suggested to persons skilled in the art and are to be included within the spirit and purview of this application.

It will also be understood that when the terms like “first” and “second” are used to describe elements, the elements are not limited by these terms. For example, a plurality of elements may be provided. Therefore, when the terms like “first” and “second” are used, it will be apparent that a plurality of such elements may be provided. In addition, the terms “first” and “second” can be selectively or exchangeably used for the elements.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

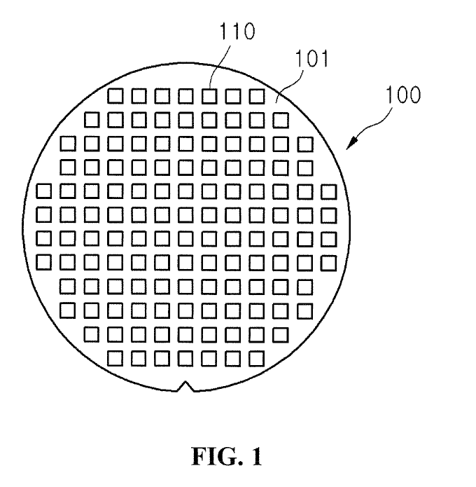

According to embodiments of the present invention, a plasma damage monitoring device can be fabricated on a test wafer. Ref erring to FIG. 1, a test wafer 100 can include at least one plasma damage monitoring device 110.

The test wafer 100 can be used to monitor the effects of a plasma process on the devices fabricated on the test wafer 100.

The plasma process being monitored can include for example, a plasma ion etching method.

According to an embodiment, the devices 110 can be arranged on the test wafer 100 at a predetermined interval. The devices 110 can be independent devices independently formed from each other. A device isolating pattern 101 can be provided between the devices 110 to maintain device independence.

Each of the devices 110 of the test wafer 100 may be affected by the plasma process. Accordingly, after the plasma process is completed, an electrical state of the devices 110 can be measured to grasp the effect of the plasma process on the devices 110. In particular, it can be appreciated that any region of the test wafer 100 is vulnerable to the plasma damage, making it possible to measure the reliability of a device on a wafer in the manufacturing process of the semiconductor device.

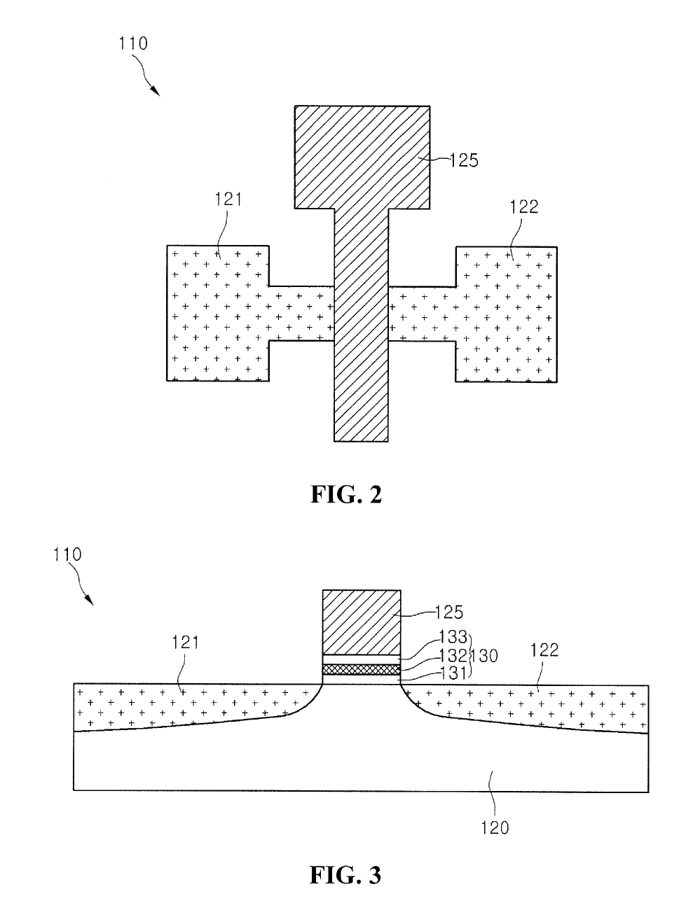

FIG. 2 is a plan view showing a device for monitoring plasma damage of a test wafer according to an embodiment, and FIG. 3 is a cross-sectional view of the device of FIG. 2 according to an embodiment.

Referring to FIGS. 2 and 3, the monitoring device 110 can include a gate pattern 125, a source region 121, and a drain region 122.

The gate pattern 125 can be formed on a semiconductor substrate 120, and the source region 121 and the drain region 122 can be formed at sides of the gate pattern 125 by the implantation of impurities at high concentration into the substrate 120.

An insulating pattern 130 can be provided between the semiconductor substrate 120 and the gate pattern 125.

In certain embodiments, the insulating pattern 130 can include a lower oxide film 131 on the semiconductor substrate 120, a nitride film 132 on the lower oxide film 131 for trapping charges, and an upper oxide film 133 on the nitride film 132.

Contact pads for the gate pattern 125, the source region 121, and the drain region 122 can each be approximately 60 μm to 100 μm in width and approximately 60 μm to 100 μm in length. The size of the contact pads can be selected to provide an area to measure voltage or current with a direct probe. Accordingly, in an embodiment, the size of a contact pad may be larger than the specified horizontal and vertical sizes.

The test wafer 100 having the monitoring devices 110 fabricated thereon can be provided to a plasma chamber to perform the plasma process.

This plasma process is used to measure how much damage is applied to the devices under particular plasma process conditions.

The effects of the plasma process on the test wafer 100 may include photon damage and charging by plasma ions.

In addition, the insulating layer pattern 130 may be affected by the plasma ions and photons of UV high energy.

The nitride film 132 of the insulating layer pattern 130 traps and accumulates charges created during the plasma process. The accumulated charges in the nitride layer 132 change the threshold Vₜ of the device.

By using the change in the threshold voltage Vₜ of the device 110, it is possible to appropriately adjust the plasma process conditions.

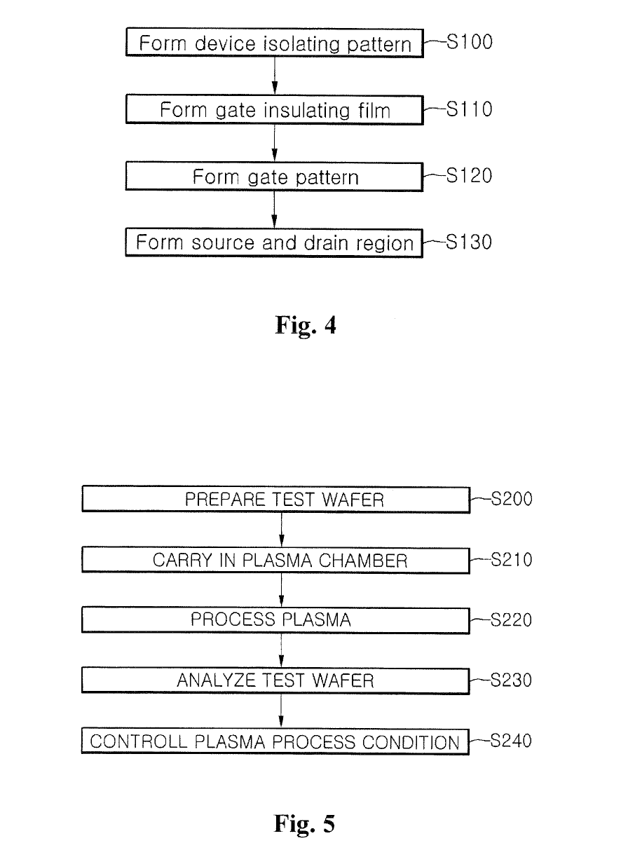

FIG. 4 is a flow chart showing a manufacturing process of a test wafer according to an embodiment.

First, in step (S100) a device isolating pattern 101 can be formed on the semiconductor substrate 120. The device isolating pattern 101 can be formed according to any suitable method known in the art.

For example, in one embodiment using a trench isolation method, the device isolating pattern 101 can include a trench and an oxide film buried in the trench.

Then, in step (S110), a gate insulating film can be formed on the semiconductor substrate 120.

The insulating film can include a lower oxide film 131, a nitride film 132, and an upper oxide film 133.

The lower oxide film 131, the nitride film 132, and the upper oxide film 133 can be formed using any suitable method known in the art. For example, a thermal oxidation or low pressure chemical vapor deposition (LPCVD) can be used. However, according to embodiments of the present invention, the lower oxide film 131, the nitride film 132, and the upper oxide film 133 are not formed by a deposition method using plasma.

In a specific embodiment, the lower oxide film 131 can be formed to a thickness of about 60 Å to about 140 Å. The nitride film 132 can be formed to a thickness of about 60 Å to about 140 Å. The upper oxide film 133 can be formed to a thickness of about 10 Å to about 40 Å.

The upper oxide film 133 can be grown on the nitride film 132 using, for example, a thermal deposition method or wet oxidation.

Then, a gate layer can be formed on the insulating film. The gate layer can include polysilicon.

The gate layer can be formed using, for example, LPCVD. However, according to embodiments of the present invention, the gate layer is not formed using a deposition method using plasma.

Then, for step (S120), a gate pattern 125 and insulating film pattern 130 can be formed by patterning the gate layer and the insulating film. The patterning process can use a photolithography process.

According to embodiments, the etching processes for forming the gate pattern 125 and insulating film pattern 130 utilize a wet etching method, not a dry etching method.

Thereafter, in step (S130), an impurity can be implanted into the semiconductor substrate 120 at both sides of the gate pattern 125 to form the source and drain regions 121 and 122. The impurity can be a single type of dopant.

In a further embodiment, a gate spacer can be formed on sidewalls of the gate pattern 125 and the insulating film pattern 130.

The devices 110 of the test wafer manufactured as above can be formed without using the etching process and the deposition process using plasma. By not using etching and deposition processes that use plasma, it is possible to reduce degradation of the device due to plasma damage before performing the plasma process under test. If plasma etching and deposition processes are used in manufacturing the monitoring device, the evaluation reliability of the test wafer 100 may be degraded.

FIG. 5 is a flow chart showing a method for evaluating plasma damage using the test wafer according to an embodiment.

First, in step (S200), a test wafer 100 for monitoring the plasma damage can be prepared. In many embodiments, the test wafer 100 can be manufactured as described with respect to FIG. 4.

The test wafer 100 can be provided into the plasma chamber (S210).

Once in the plasma chamber, the test wafer 100 can be subjected to the plasma processing (S220).

In step (S230), the test wafer 100 subjected to the plasma processing can be monitored and analyzed. For example, a region subjected to large damage by the plasma processing can be detected.

In a specific embodiment, a change in Vₜ can be detected by performing a probe measurement on the monitoring device 110 of the test wafer 100.

In the device 110 of the test wafer 100 according to an embodiment, charge trapping is generated in the nitride film 132 during the plasma process. When charge trapping is generated in the nitride film 132, the remission of charges is not generated by UV light according to the plasma. Therefore, by monitoring the charge trapping in the nitride film 132, the test wafer 100 can be useful for measuring the plasma damage.

The monitoring devices of the wafer are analyzed to properly adjust the plasma process condition used in the process for manufacturing the semiconductor device. Accordingly, for step (S240), the plasma process conditions can be controlled.

By using the subject test wafer 100, an effect of plasma formed within the plasma chamber on the wafer, not the plasma distribution within the plasma chamber, can be determined. Therefore, it is possible to determine the appropriate conditions of the plasma process.

When using the test wafer 100 for monitoring the plasma damage according to embodiments of the present invention, it is possible to immediately grasp the degree of the plasma damage per each metal layer, making it possible to analyze the process capability of individual layer of the semiconductor device.

Also, the test wafer 100 can be simply formed using the same processes for manufacturing the semiconductor device without requiring the development of a separate process.

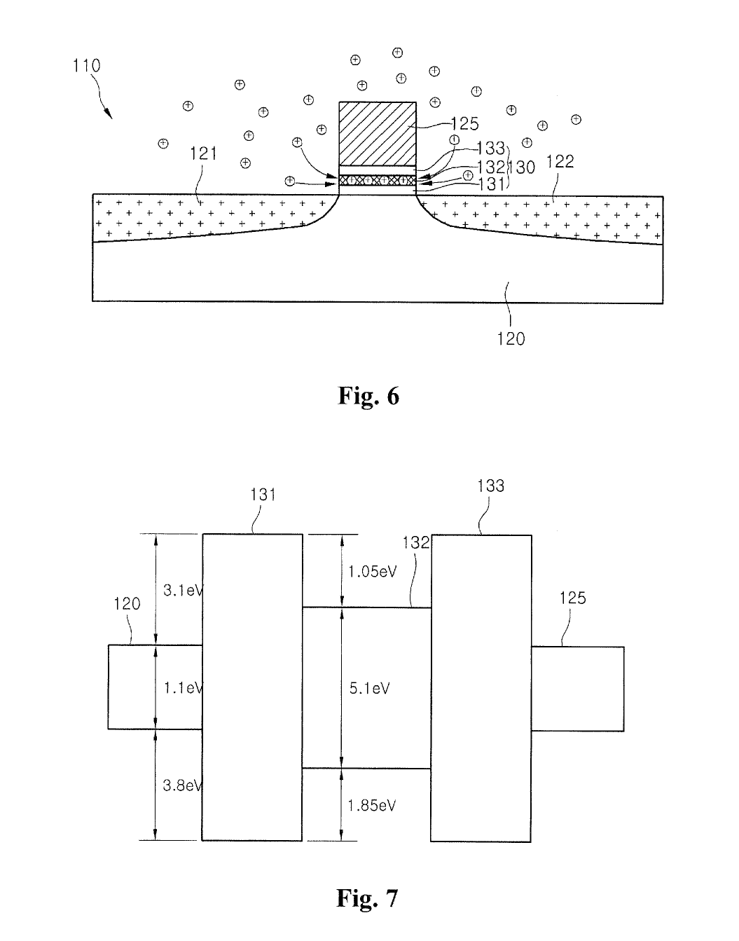

FIG. 6 is a cross-sectional view for explaining the operation of the monitoring device of the test wafer according to embodiments of the present invention. The structure of the monitoring device can be as described with reference to the drawing shown in FIG. 3.

FIG. 7 is a view showing an energy barrier of each layer of the monitoring device according to an embodiment.

As shown in FIGS. 6 and 7, the monitoring device 110 subjected to the plasma processing within the plasma chamber traps the plasma ions in the nitride film 132 of the insulating film pattern 130.

The nitride film 132 can have the role of the charge trapping layer used in a non-volatile memory device such as the silicon-oxide-nitride-oxide-silicon (SONOS) device or the nitride read only memory (NROM).

For example, referring to FIG. 7, the band gap of the semiconductor substrate 120 is 1.1 eV, the band gap of the lower oxide film 131 is 8 eV, and the band gap of the nitride film 132 is 5.1 eV. The energy barrier between the semiconductor substrate 120 and the lower oxide film 131 is 3.1 eV and 3.8 eV (to conductive band and valence band, respectively). The energy barrier between the lower oxide film 131 and the nitride film 132 is 1.05 eV and 1.85 eV (to conductive band and valence band, respectively).

Once charges are trapped in the nitride film 132, the oxide film located at the top and bottom sides of the nitride film 132 inhibit the charges from being removed from the nitride film 132. That is, the high energy barrier between the nitride film 132 and the lower oxide film 131 and between the nitride film 132 and the upper oxide film 133 supports the trapping of the charges in the nitride film 132.

Therefore, Vₜ can be measured by charges trapped in the nitride film 132, making it possible to easily evaluate the plasma damage.

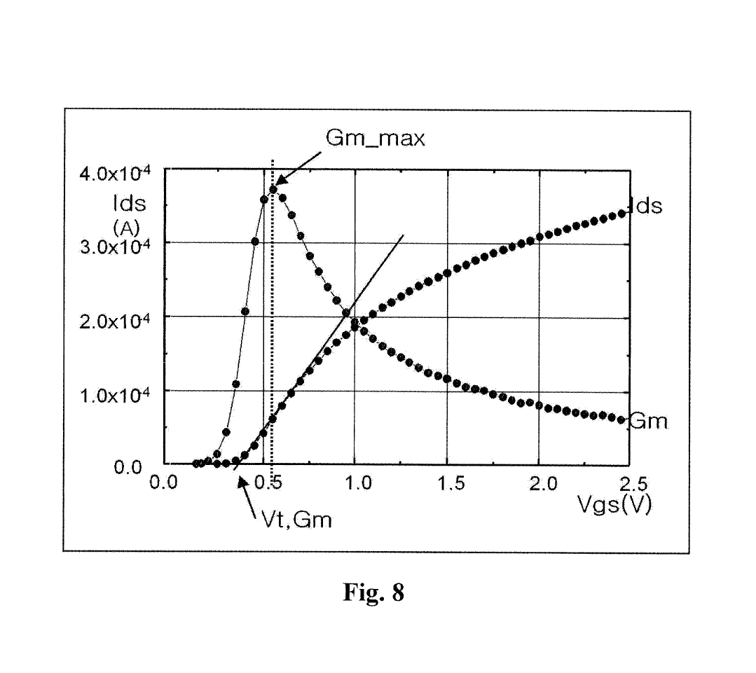

FIG. 8 is a graph illustrating the measuring of threshold voltage by probing the monitoring device according to an embodiment. The graph of FIG. 8 provides the V-I characteristic of a monitoring device having a 0.1 V applied V_{d} (drain voltage) when V_{g} (gate voltage) is varied from 0 to 2.5 V. This voltage sweep makes it possible to measure conductance Gₘ.

The maximum conductance Gₘ Max can be used to obtain the V_{g} (in this case at about 0.6 V) where a tangential slope is maximum at the V-I curve.

Therefore, the threshold voltage Vₜ can be measured at the V_{g} point where the conductance is maximum at the V-I characteristic graph.

Although the invention has been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A test wafer comprising:
a plurality of transistor devices arranged on a semiconductor substrate separated from each other in a predetermined interval,
wherein each transistor device comprises at least one device layer probe contact and a charging trap layer.

2. The test wafer according to claim 1, wherein the at least one device layer probe contact has a length of about 60 μm to about 100 μm and a width of about 60 μm to about 100 μm.

3. The test waf er according to claim 1, wherein each transistor device comprises:
a gate pattern on the semiconductor substrate;
an insulating film pattern between the semiconductor substrate and the gate pattern, the insulating film pattern comprising the charge trap layer; and
a source region and a drain region at sides of the gate pattern.

4. The test wafer according to claim 3, wherein the at least one device layer probe contact is a gate pattern contact area, a source region contact area, and a drain region contact area.

5. The test wafer according to claim 3, wherein the charging trap layer comprises a nitride film, and wherein the insulating pattern further comprises a lower oxide film arranged between the charging trap layer and the semiconductor substrate and an upper oxide film arranged between the charging trap layer and the gate pattern.

6. The test wafer according to claim 5, wherein the lower oxide film has a thickness of about 60 Å to about 140 Å.

7. The test wafer according to claim 5, wherein the nitride film has a thickness of about 60 Å to about 140 Å.

8. The test wafer according to claim 5, wherein the upper oxide film has a thickness of about 10 Å to about 40 Å.

9. A test wafer comprising a plurality of plasma damage monitoring devices on a semiconductor substrate, each plasma damage monitoring device comprising:
a gate pattern on the semiconductor substrate;
a charging trap layer between the semiconductor substrate and the gate pattern, the charging trap layer capable of trapping plasma ions; and
a source region and a drain region at sides the gate pattern,
wherein a contact area of the gate pattern, a contact area of the source region, and a contact area of the drain region are each sized for a probe contact.

10. The test wafer according to claim 9, wherein the size of the probe contact is a length of about 60 μm to about 100 μm and a width of about 60 μm to about 100 μm.

11. The test wafer according to claim 9, wherein the charging trap layer comprises a nitride film.

12. The test wafer according to claim 9, wherein the insulating pattern further comprises a lower oxide film arranged between the charging trap layer and the semiconductor substrate and an upper oxide film arranged between the charging trap layer and the gate pattern.

13. A method for manufacturing a test wafer comprising plasma damage monitoring devices, the method comprising:
forming a lower oxide film on a semiconductor substrate;
forming a nitride film on the lower oxide film;
forming an upper oxide film on the nitride film;
forming a gate layer on the upper oxide film;
forming a gate pattern and an insulating pattern by patterning the gate layer, the upper oxide film, the nitride film, and the lower oxide film; and
forming a source region and a drain region by implanting impurities into the substrate including at sides of the gate pattern.

14. The method according to claim 13, wherein forming the lower oxide film comprises performing a thermal oxidation or a low pressure chemical vapor deposition (LPCVD); and
wherein forming the nitride film comprises performing LPCVD.

15. The method according to claim 13, wherein forming the upper oxide film comprises performing a thermal oxidation, wet oxidation or LPCVD.

16. The method according to claim 13, wherein forming the gate layer comprises performing LPCVD.

17. The method according to claim 13, wherein the forming of the gate pattern and the insulating pattern uses a wet etching method.

18. The method according to claim 13, wherein the method of manufacturing the test wafer comprising the monitoring devices does not include any plasma etching processes or plasma deposition processes.

19. A method for measuring plasma damage using a test wafer, the method comprising:
preparing a test wafer comprising a plurality of transistor devices arranged on a semiconductor substrate separated from each other in a predetermined interval, wherein each transistor device comprises at least one device layer probe contact and a charging trap layer;
providing the test wafer to a plasma chamber;
performing a plasma procession on the test wafer; and
measuring an amount of charge trapped in the charging trap layer by probing the at least one device layer probe contact of the transistor devices of the test wafer.

20. The method according to claim 19, wherein measuring the amount of charge trapping in the charging trap layer comprises measuring a threshold voltage of one of the transistor devices.
